(19) United States
(12) Patent Application Publication
(10) Pub. No.: US 2026/0164735 A1
(43) Pub. Date: Jun. 11, 2026

(54) SEMICONDUCTOR DEVICE

(71) Applicant: Samsung Electronics Co., Ltd., Suwon-si (KR)

(72) Inventors: Jeonghun LEE, Suwon-si (KR); Soojin JEONG, Suwon-si (KR); Myung Gil KANG, Suwon-si (KR); Wookhyun KWON, Suwon-si (KR); Bumcheol KIM, Suwon-si (KR); Hyunmin AHN, Suwon-si (KR); Byoung Hak HONG, Suwon-si (KR)

(73) Assignee: Samsung Electronics Co., Ltd., Suwon-si (KR)

(21) Appl. No.: 19/252,283

(22) Filed: Jun. 27, 2025

(30) Foreign Application Priority Data
Dec. 10, 2024 (KR) 10-2024-0182909

(51) Int. Cl. H10D 62/13; H10D 30/00; H10D 30/43; H10D 62/10; H10D 64/27

(52) U.S. Cl. CPC H10D 62/151; H10D 30/43; H10D 30/502; H10D 62/121; H10D 64/519

(57) ABSTRACT

A semiconductor device may include a substrate including a first area and a second area, a first device on the first area, and a second device on the second area. The first device may include a first channel layer, a first inner gate electrode, a first source/drain area, and a first inner spacer. The second device may include a second channel layer, a second inner gate electrode, a second source/drain area, and a second inner spacer. A length of the first inner gate electrode in a second direction parallel to a surface of the substrate may be shorter than a length of the second inner gate electrode in the second direction. A length of the second inner spacer in the second direction may be shorter than a length of the first inner spacer in the second direction.

### CROSS-REFERENCE TO RELATED APPLICATIONS

This application claims the benefit of Korean Patent Application No. 10-2024-0182909, filed on Dec. 10, 2024, in the Korean Intellectual Property Office, the disclosure of which is incorporated herein by reference in its entirety.

### BACKGROUND

### 1. Field

The present disclosure relates to a semiconductor device.

### 2. Description of the Related Art

A fin field-effect transistor (FinFET) and a nanosheet field-effect transistor have been adopted as a technology for an integrated circuit having a highly integrated device and a higher performance. The FinFET may include a channel layer having at least three surfaces surrounded by a gate structure. The FinFET may include one or more horizontally arranged vertical fin structures. A gate-all-around (GAA) transistor, or a multi-bridge channel transistor, is an example of the nanosheet field-effect transistor. The nanosheet field-effect transistor may include one or more nanosheet channel layers vertically stacked on a substrate. The nanosheet field-effect transistor may include a gate structure surrounding all surfaces of each nanosheet channel layer among the one or more nanosheet channel layers.

### SUMMARY

An aspect of the present disclosure provides a semiconductor device where the performance of a transistor may be improved by improving a saturated drain current Idsat.

However, aspects of example embodiments of the present disclosure are not limited to the aspects described above and other aspects may be clearly understood by those skilled in the art from the following description of some example embodiments.

According to an embodiment, a semiconductor device may include a substrate comprising a first area and a second area; a first device on the first area; and a second device on the second area. The first device may include a first channel layer above the first area, a first inner gate electrode spaced apart from the first channel layer in a first direction crossing a surface of the substrate, a first source/drain area extending in the first direction and being connected to the first channel layer, and a first inner spacer between the first inner gate electrode and the first source/drain area. The second device may include a second channel layer above the second area, a second inner gate electrode spaced apart from the second channel layer in the first direction, a second source/drain area extending in the first direction and being connected to the second channel layer, and a second inner spacer between the second inner gate electrode and the second source/drain area. A second direction may be parallel to the surface of the substrate. A length of the first inner gate electrode in the second direction may be shorter than a length of the second inner gate electrode in the second direction. A length of the second inner spacer in the second direction may be shorter than a length of the first inner spacer in the second direction.

According to an embodiment, a semiconductor device may include a substrate comprising a first area and a second area; a first device on the first area; and a second device on the second area. The first device may include a plurality of first channel layers above the first area and spaced apart from each other, a first inner gate electrode spaced apart from the plurality of first channel layers in a first direction, the first direction crossing a surface of the substrate, a first source/drain area extending in the first direction and being connected to the plurality of first channel layers, and a first inner spacer between the first inner gate electrode and the first source/drain area. The second device may include a plurality of second channel layers above the second area and spaced apart from each other, a second inner gate electrode spaced apart from the plurality of second channel layers in the first direction, a second source/drain area extending in the first direction and being connected to the plurality of second channel layers, and a second inner spacer between the second inner gate electrode and the second source/drain area. A second direction may be parallel to the surface of the substrate. A length of the first inner gate electrode in the second direction may be shorter than a length of the second inner gate electrode in the second direction. A length of the second inner spacer in the second direction may be shorter than a length of the first inner spacer in the second direction.

According to an embodiment, a semiconductor device may include a substrate comprising a first area and a second area; a first device on the first area; and a second device on the second area. The first device may include a plurality of first channel layers above the first area and spaced apart from each other, a first inner gate electrode spaced apart from the plurality of first channel layers in a first direction, the first direction crossing a surface of the substrate, a first source/drain area extending in the first direction and being connected to the plurality of first channel layers, a first inner spacer between the first inner gate electrode and the first source/drain area, and a first outer gate electrode spaced apart from the first inner gate electrode in the first direction. The first outer gate electrode may not overlap the first source/drain area in a second direction. The second direction may be parallel to the surface of the substrate. The second device may include a plurality of second channel layers above the second area and spaced apart from each other, a second inner gate electrode spaced apart from the plurality of second channel layers in the first direction, a second source/drain area extending in the first direction and being connected to the plurality of second channel layers, a second inner spacer between the second inner gate electrode and the second source/drain area, and a second outer gate electrode spaced apart from the second inner gate electrode in the first direction. An area of the second outer gate electrode may not overlap the second source/drain area in the second direction. A length of the first inner gate electrode in the second direction may be shorter than a length of the second inner gate electrode in the second direction. A length of the second inner spacer in the second direction may be shorter than a length of the first inner spacer in the second direction. The first inner spacer and the first source/drain area may not overlap in the first direction. The second inner spacer and the second source/drain area may not overlap in the first direction. A ratio of the length of the first inner gate electrode in the second direction to the length of the first inner spacer in the second direction may be greater than or equal to 1 and less than or equal to 30. A ratio of the length of the second inner gate electrode in the second direction to the length of the second inner spacer in the second direction may exceed 30. A ratio of the length of the first inner gate electrode in the second direction to the length of the first inner spacer in the second direction may be greater than or equal to 0.1 and less than 1. At least a portion of the first outer gate electrode may overlap the first inner gate electrode in the first direction. At least a portion of the second outer gate electrode may overlap the second inner gate electrode in the first direction.

According to an embodiment, a method of manufacturing a semiconductor device, may include forming a first device on a first area of a substrate and a second device on a second area of the substrate. The first device may include a first channel layer above the first area, a first inner gate electrode spaced apart from the first channel layer in a first direction crossing a surface of the substrate, a first source/drain area extending in the first direction and being connected to the first channel layer, and a first inner spacer between the first inner gate electrode and the first source/drain area. The second device may include a second channel layer above the second area, a second inner gate electrode spaced apart from the second channel layer in the first direction, a second source/drain area extending in the first direction and being connected to the second channel layer, and a second inner spacer between the second inner gate electrode and the second source/drain area. A second direction of the substrate may be parallel to the surface of the substrate. A length of the first inner gate electrode in the second direction may be shorter than a length of the second inner gate electrode in the second direction. A length of the second inner spacer in the second direction may be shorter than a length of the first inner spacer in the second direction.

In some embodiments, the first inner spacer and the first source/drain area may not overlap in the first direction, and the second inner spacer and the second source/drain area may not overlap in the first direction.

In some embodiments, a ratio of the length of the first inner gate electrode in the second direction to the length of the first inner spacer in the second direction may be greater than or equal to 1 and less than or equal to 30.

In some embodiments, a ratio of the length of the second inner gate electrode in the second direction to the length of the second inner spacer in the second direction may exceed 30.

In some embodiments, a ratio of the length of the first inner gate electrode in the second direction to the length of the second inner gate electrode in the second direction may be greater than or equal to 0.1 and less than 1.

Additional aspects of example embodiments will be set forth in part in the description which follows and, in part, will be apparent from the description.

### BRIEF DESCRIPTION OF THE FIGURES

These and/or other aspects, features, and advantages of inventive concepts will become apparent and more readily appreciated from the following description of example embodiments, taken in conjunction with the accompanying drawings of which:

FIG. 1 is an example layout diagram illustrating a semiconductor device according to an example embodiment of the present disclosure;

FIG. 2 is an example diagram illustrating a cross section taken along line A-A′ of FIG. 1;

FIG. 3 is an example diagram illustrating a cross section taken along line B-B′ of FIG. 1;

FIG. 4 is an example diagram illustrating a cross section taken along line C-C′ of FIG. 1;

FIG. 5 is an example diagram illustrating a cross section taken along line D-D′ of FIG. 1;

FIG. 6 is an example layout diagram illustrating a semiconductor device according to an example embodiment of the present disclosure;

FIG. 7 is an example diagram illustrating a cross section taken along line E-E′ of FIG. 6;

FIG. 8 is an example diagram illustrating a cross section taken along line F-F′ of FIG. 6; and

FIGS. 9 through 18 are example diagrams for describing a method of fabricating a semiconductor device according to an example embodiment.

### DETAILED DESCRIPTION

Before the present disclosure is described, terms or words used in the present disclosure and the accompanying claims are not to be limited to general definitions or dictionary definitions. The terms and words are to be construed under a principle that an inventor may appropriately define a concept of a term in order to describe embodiments of inventive concepts in the best way. Example embodiments described in the present disclosure and configurations illustrated in the accompanying drawings are merely for describing inventive concepts and do not represent all of the technical spirit of the present disclosure. Thus, it should be understood that various equivalents and modifications may replace the presented embodiments and configurations, and may be present at the time of filing the application of the present disclosure.

The same reference numerals or symbols illustrated in the accompanying drawings represent components or elements performing substantially identical functions. For convenience for description and understanding, example embodiments different from each other may be described with the same reference numerals or symbols. In other words, although a plurality of drawings illustrates elements having the same reference numeral, the plurality of drawings does not mean only one example embodiment.

In the present disclosure, when an element is described as being “directly on” or “in contact with” another element, it may be understood that the element is in direct contact with or connected to the other element or that still another element is absent between them.

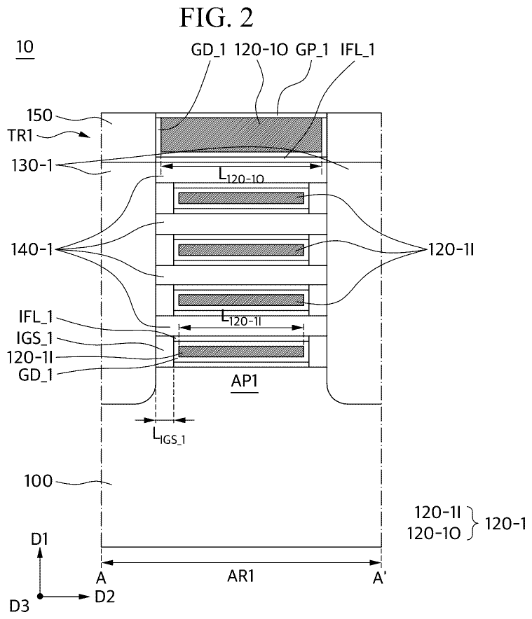

Also, in the present disclosure, when an element is described as being “above” or “on an upper surface of” another element, it may be understood that the element is present over the other element in a vertical direction. For example, the element may be understood as being over the other element in a direction D1 in a diagram (e.g., FIG. 2). They may be in direct contact or directly connected. Alternatively, they may be indirectly connected such that it may be understood that still another element may be present between them. This may be similarly applied to a case in which an element is described as being “over” another element.

In addition, in the present disclosure, when an element is described as being “below” or “on a lower surface of” another element, it may be understood that the element is present under the other element in a vertical direction. For example, the element may be understood as being under the other element in a direction D1 in a diagram (e.g., FIG. 2). They may be in direct contact or directly connected, but it may be understood that still another element is present between them. This may be similarly applied to a case in which an element is described as being “under” another element.

Another similar expression for describing a relationship between the positions of elements may be construed similarly to the above.

In the following descriptions, terms in a singular form include terms in a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In addition, it should be noted in advance that an expression such as an upper side, an upper surface, a lower side, a lower surface, a side surface, a front surface, or a rear surface is based on directions illustrated in the drawings and that the expression may be changed when a direction of a corresponding object is changed.

Terms including an ordinal number such as “first” or “second” used in the present specification and claims may be used to distinguish elements. Such an ordinal number is used to contextually distinguish identical or similar elements from each other. Meanings of the terms may not be limited by use of the ordinal number. For example, a use order, a disposition order, or the like of elements with such an ordinal number may not be limitedly construed by the number. Ordinal numbers may be substituted with each other.

A physical property described in the present disclosure may be measured at normal temperature and pressure unless specifically limited. The normal temperature in the present disclosure may be non-manipulated natural temperature within a range from 10 degrees Celsius (° C.) to 30° C., from 20° C. to 28° C., or from 22° C. to 26° C. In an example embodiment, the normal temperature may be 25° C. The normal pressure in the present disclosure may be non-manipulated natural pressure within a range from 700 millimeters of mercury (mmHg) to 800 mmHg or from 720 mmHg to 780 mmHg. In an example embodiment, the normal pressure may be 760 mm Hg.

The drawings illustrated in the present disclosure are according to mere example embodiments, and the ratio of the width, the length and the height (or the thickness) of each element is for detailed descriptions for the example embodiments, and thus the ratio may differ from reality. Further, in the coordinate system illustrated in the drawings, each axis may be perpendicular to each other, and the direction the arrow points may be the +direction, and the direction opposite to the direction indicated by the arrow (rotated by 180 degrees) may be the −direction.

Materiality mentioned in the present disclosure may have a unit according to the International System of Units unless particularly defined.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The drawings which is associated with a semiconductor device according to an example embodiment of the present disclosure illustrate a fin field-effect transistor or a nanosheet field effect transistor as an example, but it is merely an example. In an example embodiment, the semiconductor device may include one or more of a tunneling field-effect transistor (FET), a three-dimensional transistor, and a vertical FET. In an example embodiment, the semiconductor device may include a planar transistor. Also, in an example embodiment, the semiconductor device may be applied to a two-dimensional (2D) material-based FET and a heterostructure thereof. In an example embodiment, the semiconductor device may include one or more of a bipolar junction transistor and a lateral double diffused FET.

Hereinafter, the example embodiments of the present disclosure will be described with reference to the drawings. In addition, existing elements, structures, or layers of the semiconductor device according to an example embodiment may or may not be described in detail in the present disclosure for simplicity. For example, a description for one or more contact structures included in the semiconductor device, isolation structures of a field-effect transistor, another structure, or a material forming the above-described structures may be omitted when hardly associated with new features of the example embodiments.

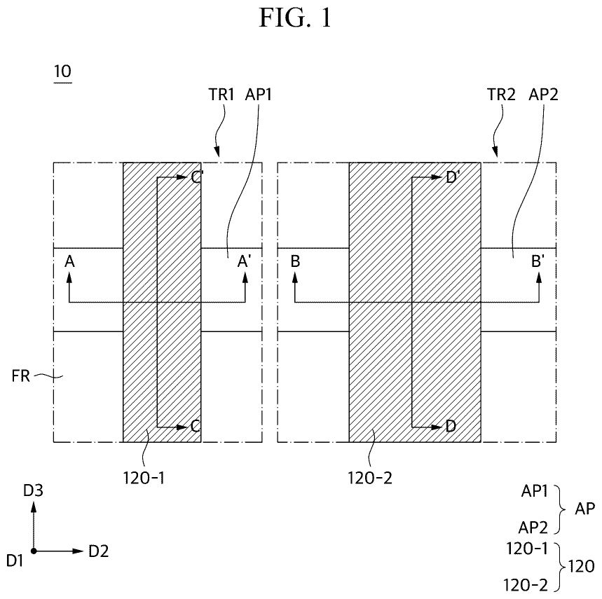

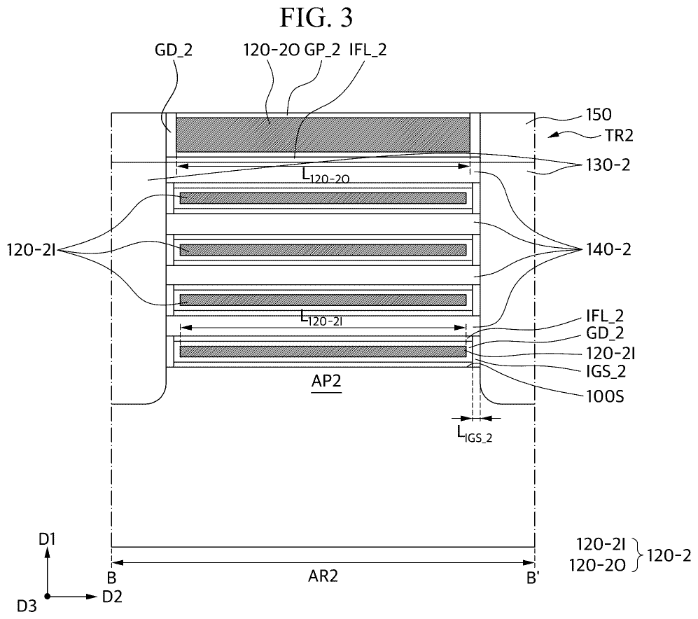

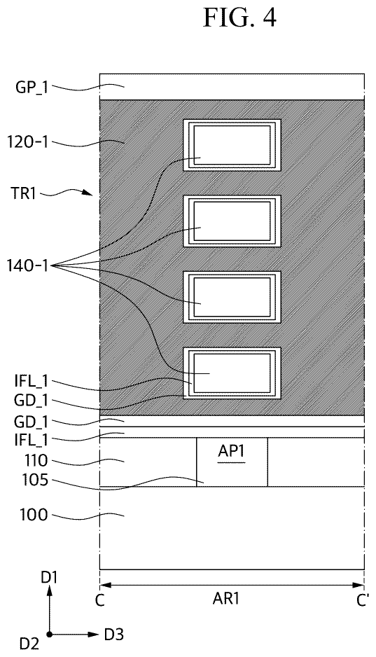

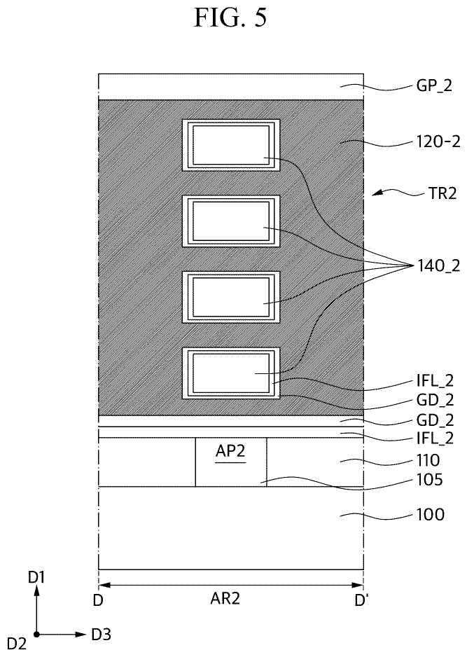

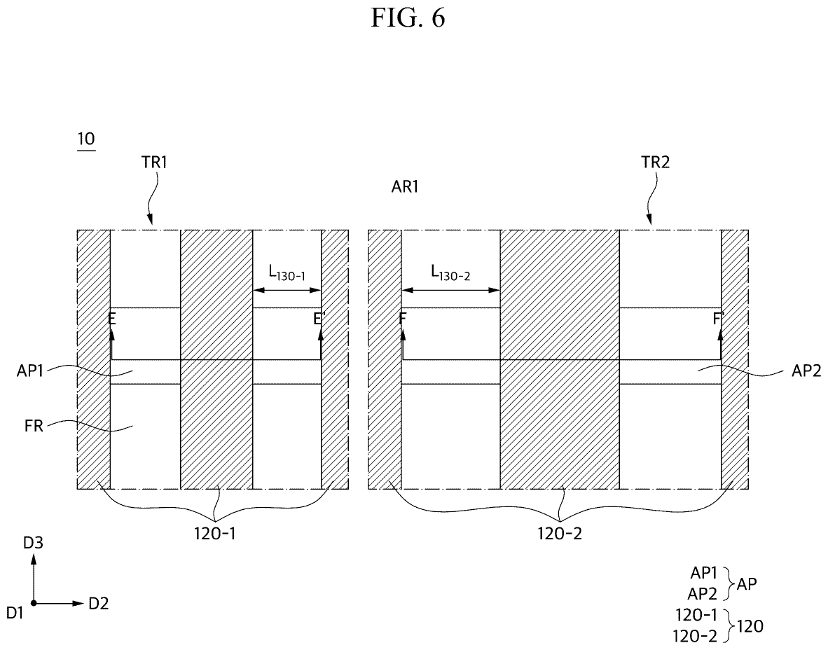

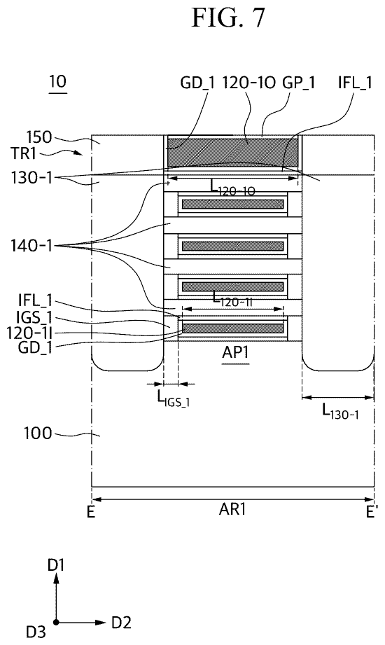

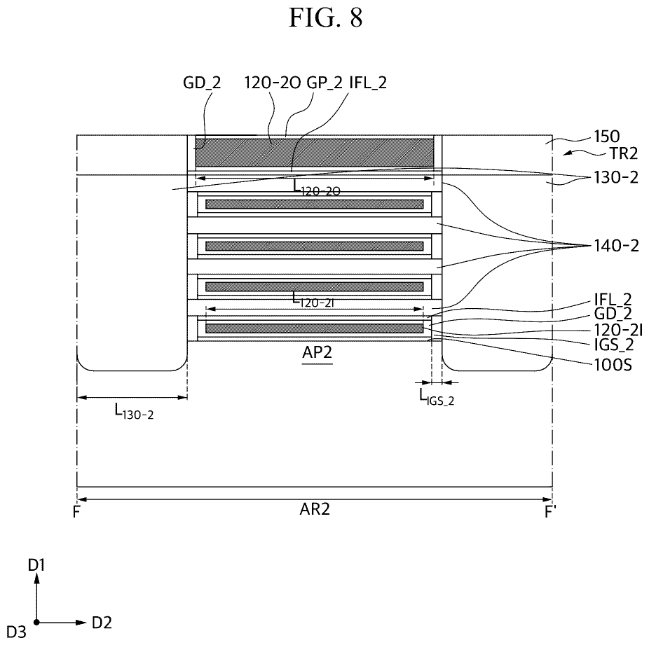

FIG. 1 is an example layout diagram illustrating a semiconductor device 10 according to an example embodiment of the present disclosure. FIG. 2 is an example diagram illustrating a cross section taken along line A-A′ of FIG. 1. FIG. 3 is an example diagram illustrating a cross section taken along line B-B′ of FIG. 1. FIG. 4 is an example diagram illustrating a cross section taken along line C-C′ of FIG. 1. FIG. 5 is an example diagram illustrating a cross section taken along line D-D′ of FIG. 1. FIG. 6 is an example layout diagram illustrating the semiconductor device 10 according to an example embodiment of the present disclosure. FIG. 7 is an example diagram illustrating a cross section taken along line E-E′ of FIG. 6. FIG. 8 is an example diagram illustrating a cross section taken along line F-F′ of FIG. 6.

A first direction D1 in the present disclosure may be a direction perpendicular to a surface 100S of a substrate. A second direction D2 may be a direction crossing the first direction D1. The second direction D2 may be, for example, a direction parallel to the surface 100S of the substrate. A third direction D3 may be a direction crossing the first direction D1 and the second direction D2. A third direction D3 may be, for example, a direction parallel to the surface 100S of the substrate. For example, the first direction D1 and the second direction D2 may be perpendicular to each other, the second direction D2 and the third direction D3 may be perpendicular to each other, and the first direction D1 and the third direction D3 may be perpendicular to each other.

In the present disclosure, electrical conductivity of an insulation material may be less than or equal to 10⁻⁶ Siemens per meter (S/m). The electrical conductivity is not particularly limited, but may be, for example, measured with ASTM E1004. For example, the insulation material may include one or more selected from a group including silicon oxide, silicon-germanium oxide, germanium oxide, silicon oxynitride, silicon nitride, a high-permittivity material having a dielectric constant higher than that of silicon oxide, and a low-permittivity material having a dielectric constant lower than that of silicon oxide. The high-permittivity material may include, for example, one or more from a group including boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but it is merely an example. The low-permittivity material may include, for example, one or more from a group including fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, and mesoporous silica, but it is merely an example.

In the present disclosure, electrical conductivity of a conductive material may be greater than or equal to 10⁶ S/m. For example, the conductive material may include at least one of a metal, a metal alloy, a conductive metallic nitride, a metallic silicide, a doped semiconductor material, a conductive metallic oxide, and a conductive metallic oxynitride. For example, the conductive material may include at least one selected from a group including titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), and vanadium (V), but it is merely an example. The conductive metallic oxide and the conductive metallic oxynitride may include a form in which the above-described substance is oxidized, but it is merely an example.

In an example embodiment, the semiconductor device 10 may include a substrate 100, a first device TR1, and a second device TR2. The semiconductor device 10 may include a long channel (LC) device and a short channel (SC) device.

In an example embodiment, the substrate 100 may be bulk silicon or silicon-on-insulator (SOI). In contrast, the substrate 100 may be a silicon substrate or include another material such as silicon germanium, silicon germanium on insulator (SGOI), indium antimonide, lead telluride, indium arsenide, gallium arsenide, or gallium antimonide, but it is merely an example.

In an example embodiment, the semiconductor device 10 may include an active pattern AP and a field pattern FR. The active pattern AP may be extended and disposed in the second direction D2. A plurality of active patterns AP may be disposed, and active patterns AP adjacent to each other may be spaced apart from each other. For example, the active patterns AP adjacent to each other may be spaced apart from each other in the third direction D3. The field pattern FR may be disposed between the active patterns AP spaced apart from each other. The field pattern FR may form a boundary between the active patterns AP adjacent to each other.

In an example embodiment, the field pattern FR may be defined by a general trench, but it is merely an example embodiment. Meanwhile, it is apparent that those skilled in the art to which the present disclosure belongs may distinguish what portion the field area FR is and what portion the active pattern AP is. The field pattern FR may have a shallow trench isolation (STI) structure, but it is merely an example.

In an example embodiment, the semiconductor device 10 may include an element separator (not illustrated) disposed near the active pattern AP. The field pattern FR may be disposed in an area of the element separator, which is between the active patterns AP adjacent to each other. In an example embodiment, the active pattern AP may include a fin structure or a nanosheet, and the field pattern FR may be an area not including the fin structure or the nanosheet.

In an example embodiment, the substrate 100 may include a first area AR1 and a second area AR2. When viewed in the first direction D1, the first area AR1 and the second area AR2 may not overlap each other. The active pattern AP may include a first active pattern AP1 disposed on the first area AR1 and a second active pattern AP2 disposed on the second area AR2.

In an example embodiment, the first device TR1 may be disposed in the first area AR1. In an example embodiment, the second device TR2 may be disposed in the second area AR2. The first device TR1 and the second device TR2 may be disposed to be spaced apart from each other. For example, the first device TR1 and the second device TR2 may be spaced apart in the second direction D2.

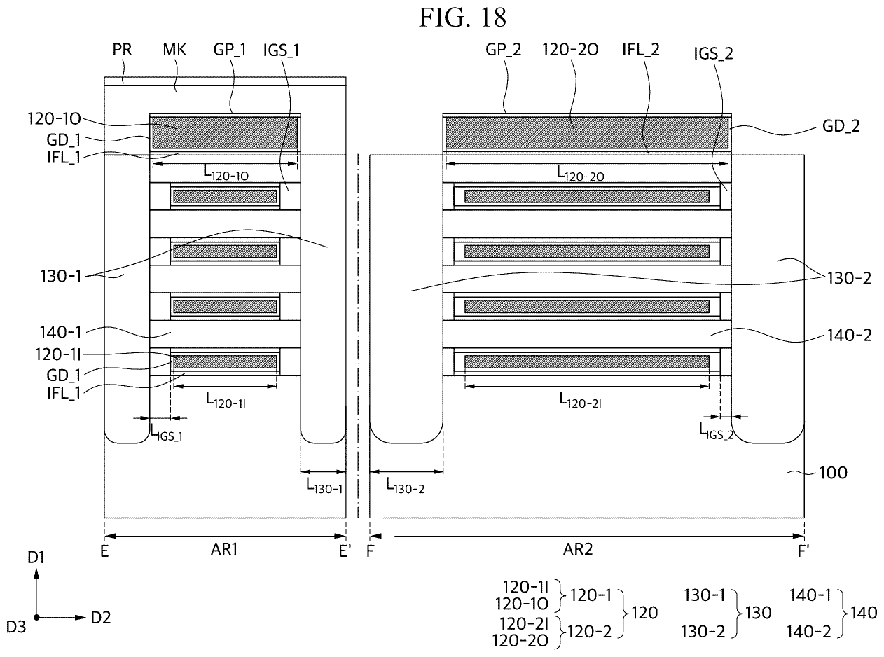

In an example embodiment, the active pattern AP may include one or more channel layers 140 (see FIG. 18). The active pattern AP may include a plurality of channel layers 140, and the plurality of channel layers 140 may be spaced apart from each other. For example, the plurality of channel layers 140 may be spaced apart from each other in the first direction D1. A channel layer 140 may be extended and disposed in the second direction D2. The channel layer 140 may have a form of a sheet, but it is merely an example. A drawing illustrates that four channel layers 140 are formed, but it is merely for convenience for description, and one, two, or more channel layers 140 may be formed.

In an example embodiment, the channel layer 140 may include one or more of silicon (Si) and germanium (Ge). In another example embodiment, the channel layer 140 may include a compound semiconductor. In the present disclosure, the compound semiconductor may include a group IV-IV compound semiconductor or a group III-IV compound semiconductor and specifically may include a binary compound or a ternary compound including at least two or more of carbon (C), silicon (Si), germanium (Ge), and tin (Sn) or a compound obtained by doping the above-described compounds with a group IV element. In an example embodiment, the group III-V compound semiconductor may be, for example, one of a binary compound, a ternary compound, or a quaternary compound formed in combination of at least one of aluminum (Al), gallium (Ga), and indium (In) of group III elements and one of phosphorus (P), arsenic (As), and antimony (Sb) of group V elements.

In an example embodiment, the channel layer 140 may include a first channel layer 140-1 disposed above the first area AR1 and a second channel layer 140-2 disposed above the second area AR2.

In an example embodiment, the semiconductor package 10 may include a gate electrode 120. The gate electrode 120 may be extended and disposed in the third direction D3. A plurality of gate electrode 120 may be disposed, and gate electrodes 120 adjacent to each other may be spaced apart from each other. For example, the gate electrodes 120 adjacent to each other may be spaced apart from each other in the second direction D2. The gate electrode 120 may be electrically connected to the active pattern AP. In an example embodiment, the gate electrode 120 may include a conductive material.

In an example embodiment, the gate electrode 120 may include a first gate electrode 120-1 disposed above the first area AR1 and a second gate electrode 120-2 disposed above the second area AR2.

In an example embodiment, the first device TR1 may include the first gate electrode 120-1. The first gate electrode 120-1 may include a first inner gate electrode 120-1I spaced apart from the first channel layer 140-1 in the first direction D1.

In an example embodiment, the first device TR1 may include a plurality of first channel layers 140-1 disposed above the first area AR1 and spaced apart from each other. The second device TR2 may include a plurality of second channel layers 140-2 disposed above the second area AR2 and spaced apart from each other.

In an example embodiment, the plurality of first channel layers 140-1 may be spaced apart in the first direction D1, and the first inner gate electrode 120-1I may be disposed between first channel layers 140-1 adjacent to each other among the plurality of first channel layers 140-1. For example, the plurality of first channel layers 140-1 may be spaced apart from each other in the first direction D1 at equal intervals.

In an example embodiment, the second device TR2 may include the second gate electrode 120-2. The second gate electrode 120-2 may include a second inner gate electrode 120-2I spaced apart from the second channel layer 140-2 in the first direction D1.

In an example embodiment, the plurality of second channel layers 140-2 may be spaced apart in the first direction D1, and the second inner gate electrode 120-2I may be disposed between second channel layers 140-2 adjacent to each other among the plurality of second channel layers 140-2. For example, the plurality of second channel layers 140-2 may be spaced apart from each other in the first direction D1 at equal intervals.

In an example embodiment, a length L_{120-1I} of the first inner gate electrode 120-1I in the second direction D2 may be shorter than a length L_{120-2I} of the second inner gate electrode 120-2I in the second direction D2. The short channel device and the long channel device may be distinguished through lengths L_{120-1I} and L_{120-2I} of inner gate electrodes 120-1I and 120-2I in the second direction D2. That is, the first device TR1 may be the short channel device, and the second device TR2 may be the long channel device.

In an example embodiment, a ratio L_{120-1I}/L_{120-2I} of the length L_{120-1I} of the first inner gate electrode 120-1I in the second direction D2 to the length L_{120-2I} of the second inner gate electrode 120-2I in the second direction D2 may be greater than or equal to 0.1 and less than 1. The above-described ratio L_{120-1I}/L_{120-2I} may be greater than or equal to 0.2, 0.3, 0.4, or 0.5, but it is merely an example.

In an example embodiment, the semiconductor device 10 may include a source/drain area 130 connected to the channel layer 140 (see FIG. 18). The source/drain area 130 may include an impurity, and a type of the impurity may vary depending on a conductivity type. For example, an n-type one may include an n-type dopant that is an impurity including one or more of phosphorus (P), arsenic (As), antimony (Sb), and bismuth (Bi), and a p-type one may include a p-type dopant that is an impurity including one or more of boron (B) and gallium (Ga). A plurality of source/drain areas 130 may be disposed, and at least a portion of the plurality of source/drain areas 130 may have n-type or p-type conductivity. In addition, a portion of the plurality of source/drain areas 130 may have n-type conductivity, and another portion thereof may have p-type conductivity.

In an example embodiment, the first device TR1 may include the first channel layer 140-1 disposed above the first area AR1. The first device TR1 may include a first source/drain area 130-1 connected to the first channel layer 140-1. The first source/drain area 130-1 may be extended, for example, in the first direction D1. A plurality of first source/drain areas 130-1 may be disposed. First source/drain areas 130-1 adjacent to each other among the plurality of first source/drain areas 130-1 may be spaced apart from each other. For example, the plurality of first source/drain areas 130-1 may be spaced apart in the second direction D2. At least a portion of the first channel layers 140-1 may be disposed between the first source/drain areas 130-1 adjacent to each other among the plurality of first source/drain areas 130-1.

In an example embodiment, the second device TR2 may include a second channel layer 140-2 disposed above the second area AR2. The second device TR2 may include a second source/drain area 130-2 connected to the second channel layer 140-2. The second source/drain area 130-2 may be extended, for example, in the first direction D1. A plurality of second source/drain areas 130-2 may be disposed. Second source/drain areas 130-2 adjacent to each other among the plurality of second source/drain areas 130-2 may be spaced apart from each other. For example, the plurality of second source/drain areas 130-2 may be spaced apart in the second direction D2. At least a portion of the second channel layers 140-2 may be disposed between the second source/drain areas 130-2 adjacent to each other among the plurality of second source/drain areas 130-2.

In an example embodiments, when viewed in the second direction D2, the first inner gate electrode 120-1I may overlap the first source/drain area 130-1 in at least some areas. In an example embodiments, when viewed in the second direction D2, the second inner gate electrode 120-2I may overlap the second source/drain area 130-2 in at least some areas.

In an example embodiment, the first gate electrode 120-1 may include a first outer gate electrode 120-1O spaced apart from the first inner gate electrode 120-1I in the first direction D1. The first outer gate electrode 120-1O may have an area not overlapping the first source/drain area 130-1 when viewed in the second direction D2.

In an example embodiment, the second gate electrode 120-2 may include a second outer gate electrode 120-2O spaced apart from the second inner gate electrode 120-2I in the first direction D1. The second outer gate electrode 120-2O may have an area not overlapping the second source/drain area 130-2 when viewed in the second direction D2.

In an example embodiment, a plurality of first inner gate electrodes 120-1I may be disposed. First inner gate electrodes 120-1I adjacent to each other among the plurality of first inner gate electrodes 120-1I may be spaced apart in the first direction D1. The first channel layer 140-1 may be disposed between the first inner gate electrodes 120-1I adjacent to each other. The first inner gate electrode 120-1I may surround at least a portion of the first channel layer 140-1.

In an example embodiment, a plurality of second inner gate electrodes 120-2I may be disposed. Second inner gate electrodes 120-2I adjacent to each other among the plurality of second inner gate electrodes 120-2I may be spaced apart in the first direction D1. The second channel layer 140-2 may be disposed between the second inner gate electrodes 120-2I adjacent to each other. The second inner gate electrode 120-2I may surround at least a portion of the second channel layer 140-2.

Referring to FIGS. 2 and 3, a length L_{120-1O} of the first outer gate electrode 120-1O in the second direction D2 may be shorter than a length L_{120-2O} of the second outer gate electrode 120-2O in the second direction D2. The short channel device and the long channel device may be distinguished through lengths L_{120-1O} and L_{120-2O} of outer gate electrodes 120-1O and 120-2O in the second direction D2 as well as the above-described lengths L_{120-1I} and L_{120-2I} of the inner gate electrodes 120-1I and 120-2I in the second direction D2. That is, the first device TR1 may be the short channel device, and the second device TR2 may be the long channel device.

Referring to FIG. 2, the length L_{120-1O} of the first outer gate electrode 120-1O in the second direction D2 may be longer than the length L_{120-1I} of the first inner gate electrode 120-1I in the second direction D2. Through this, an electric current flowing in the channel layer 140 (see FIG. 18) of the semiconductor device 10 may be improved.

Referring to FIG. 3, the length L_{120-2O} of the second outer gate electrode 120-2O in the second direction D2 may be longer than the length L_{120-2I} of the second inner gate electrode 120-2I in the second direction D2. Through this, the electric current flowing in the channel layer 140 (see FIG. 18) of the semiconductor device 10 may be improved.

In an example embodiments, when viewed in the first direction d1, the first outer gate electrode 120-1O may overlap the first inner gate electrode 120-1I in at least some areas. In an example embodiments, when viewed in the first direction d1, the second outer gate electrode 120-2O may overlap the second inner gate electrode 120-2I in at least some areas.

In an example embodiment, the semiconductor package 10 may include a protrusion pattern 105 disposed on the substrate 100. The protrusion pattern 105 may be disposed to each of the first device TR1 and the second device TR2. The protrusion pattern 105 may protrude from the surface 100S of the substrate in the first direction and may be extended in the second direction D2. In an example embodiment, the protrusion pattern 105 may be a portion of the substrate 100 and formed by etching a portion of the substrate 100. In another example embodiment, the protrusion pattern 105 may include an epitaxial layer grown from the substrate 100. The protrusion pattern 105 may include one or more of silicon and germanium that are elemental semiconductor materials. In another example embodiment, the protrusion pattern 105 may include a compound semiconductor.

In an example embodiment, when viewed in the first direction D1, the protrusion pattern 105 may overlap the channel layer 140 in at least some areas. In other words, the channel layer 140 may be disposed above the protrusion pattern 105.

In an example embodiment, the semiconductor device 10 may include a field insulation film 110 disposed to the field pattern FR. The field insulation film 110 may be disposed on the substrate 100. The field insulation film 110 may cover a side wall of the protrusion pattern 105. The field insulation film 110 may be disposed so that an upper surface thereof is at a level substantially equal to that of an upper surface of the protrusion pattern 105 in the first direction D1. Unlike an illustration, as another example, the field insulation film 110 may cover only a portion of the side wall of the protrusion pattern 105. In this case, a portion of the protrusion pattern 105 may protrude in the first direction D1 further than the field insulation film 110. The protrusion pattern 105 may be a single film or may be, in another example embodiment, a plurality of films. In an example embodiment, the field insulation film 110 may include an insulation material.

In an example embodiment, the first device TR1 may include a first inner spacer IGS_1 disposed between the first inner gate electrode 120-1I and the first source/drain area 130-1. In an example embodiment, the second device TR2 may include a second inner spacer IGS_2 disposed between the second inner gate electrode 120-2I and the second source/drain area 130-2. Each of the first inner spacer IGS_1 and the second inner spacer IGS_2 may include independently include an insulation material.

In an example embodiment, a length L_{IGS_2} of the second inner spacer IGS_2 in the second direction D2 may be shorter than a length L_{IGS_1} of the first inner spacer IGS_1 in the second direction D2. Through this, a saturated drain current Idₛₐₜ may be improved, so that deterioration of performance of the semiconductor device 10 may be improved.

According to example embodiments, it is possible to provide a semiconductor device of which performance of a transistor is improved by improving a saturated drain current Idₛₐₜ.

In an example embodiments, when viewed in the first direction D1, the first inner spacer IGS_1 and the first source/drain area 130-1 may not overlap. In an example embodiments, when viewed in the first direction D1, the first inner spacer IGS_1 may overlap the first channel layer 140-1 in at least some areas.

In an example embodiments, when viewed in the second direction D1, the second inner spacer IGS_2 and the second source/drain area 130-2 may not overlap. When viewed in the first direction D1, the second inner spacer IGS_2 may overlap the second channel layer 140-2 in at least some areas.

In an example embodiment, a ratio L_{120-1I}/L_{IGS_1} of the length L_{120-1I} of the first inner gate electrode 120-1I in the second direction D2 to the length L_{IGS_1} of the first inner spacer IGS_1 in the second direction D2 may be greater than or equal to 1, 1.5, 2, 2.5, 3, 3.5, 4, 4.5, 5, 5.5, 6, 6.5, 7, 7.5, 8, 8.5, 9, 9.5, or 10 or may be less than or equal to 30, 28, 26, 24, 22, 20, 18, 16, 14, or 12. The above-described ratio L_{120-1I}/L_{IGS_1} may be present within a range formed by selecting the above described upper limit and lower limit. Through this, the deterioration of the performance of the semiconductor device 10 may be improved.

In an example embodiment, a ratio L_{120-2I}/L_{IGS_2} of the length L_{120-2I} of the second inner gate electrode 120-2I in the second direction D2 to the length L_{IGS_2} of the second inner spacer IGS_2 in the second direction D2 may exceed 30 or be greater than or equal to 31, 32, 33, 34, 35, 36, 37, 38, 39, 40, 41, 42, 43, 44, or 45 or may be less than or equal to 100, 95, 90, 85, 80, 75, 70, 65, 60, 55, or 50. The above-described ratio L_{120-2I}/L_{IGS_2} may be present within a range formed by selecting the above described upper limit and lower limit. Through this, the deterioration of the performance of the semiconductor device 10 may be improved.

In an example embodiment, the semiconductor package 10 may include a gate insulation film disposed above the field insulation film 110. The first device TR1 may include a first gate insulation film GD_1 disposed above the field insulation film 110, and the second device TR2 may include a second gate insulation film GD_2 disposed above the field insulation film 110.

In an example embodiment, the first gate insulation film GD_1 may surround at least a portion of the first channel layer 140-1. The first inner gate electrode GD_1 may be disposed around the first channel layer 140-1. The second gate insulation film GD_2 may surround at least a portion of the second channel layer 140-2. The second gate insulation film GD_2 may be disposed around the second channel layers 140-2. Each of the first gate insulation film GD_1 and the second gate insulation film GD_2 may independently include an insulation material. For example, each of the first gate insulation film GD_1 and the second gate insulation film GD_2 may include one or more selected from a group including silicon oxide, silicon-germanium oxide, germanium oxide, silicon oxynitride, silicon nitride, and a high-permittivity material. Each of the first gate insulation film GD_1 and the second gate insulation film GD_2 may be independently a single film or may be, in another example embodiment, a plurality of films.

In an example embodiment, the semiconductor package 10 may include an interface film disposed between the gate electrode 120 and the channel layer 140. The first device TR1 may include a first interface film IFL_1 disposed between the first gate electrode 120-1 and the first channel layer 140-1. The second device TR2 may include a second interface film IFL_2 disposed between the second gate electrode 120-2 and the second channel layer 140-2. Each of the first interface film IFL_1 and the second interface film IFL_2 may independently include an insulation material. For example, each of the first interface film IFL_1 and the second interface film IFL_2 may include one or more selected from a group including silicon oxide, silicon-germanium oxide, germanium oxide, silicon oxynitride, silicon nitride, and a high-permittivity material. Each of the first interface film IFL_1 and the second interface film IFL_2 may be independently a single film or may be, in another example embodiment, a plurality of films.

In an example embodiment, at least a portion of the first interface film IFL_1 may be disposed between the first inner gate electrode 120-1I and the substrate 100, between the first inner gate electrode 120-1I and the first channel layer 140-1, and between the first outer gate electrode 120-1O and the first channel layer 140-1.

In an example embodiment, at least a portion of the second interface film IFL_2 may be disposed between the second inner gate electrode 120-2I and the substrate 100, between the second inner gate electrode 120-2I and the second channel layer 140-2, and between the second outer gate electrode 120-2O and the second channel layer 140-2.

In an example embodiment, the semiconductor device 10 may include a gate capping film disposed above the gate electrode 120. The first device TR1 may include a first gate capping film GP_1 disposed on the first outer gate electrode 120-1O. The second device TR2 may include a second gate capping film GP_2 disposed on the second outer gate electrode 120-2O. Each of the first gate capping film GP_1 and the second gate capping film GP_2 may independently include an insulation material. For example, each of the first gate insulation film GD_1 and the second gate insulation film GD_2 may include one or more selected from a group including silicon oxide, silicon-germanium oxide, germanium oxide, silicon oxynitride, silicon nitride, and a high-permittivity material. Each of the first gate capping film GP_1 and the second gate capping film GP_2 may be independently a single film or may be, in another example embodiment, a plurality of films.

In an example embodiment, the semiconductor package 10 may include an inter-layer insulation film 150 of which at least a portion is disposed on the source/drain area 130. The at least a portion of the inter-layer insulation film 150 may be disposed on the first source/drain area 130-1 and also on the second source/drain area 130-2. The inter-layer insulation film 150 may include an insulation material. For example, the inter-layer insulation film 150 may include one or more selected from a group including silicon oxide, silicon-germanium oxide, germanium oxide, silicon oxynitride, silicon nitride, and a high-permittivity material. The inter-layer insulation film 150 may be a single film or may be, in another example embodiment, a plurality of films.

In an example embodiment, although not illustrated in a drawing, the semiconductor package 10 may include a wiring line. The wiring line may include a power line that supplies power to the semiconductor device 10 and a signal line that sends an electrical signal. The wiring line may be a single-layer structure or may be a multilayered structure including a wiring filling film and a wiring barrier film surrounding at least a portion of a surface of the wiring filling film. The wiring line may include a conductive material. For example, the wiring filling film may include one selected from a group including aluminum (Al), tungsten (W), cobalt (Co), ruthenium (Ru), copper (Cu), silver (Ag), gold (Au), manganese (Mn), and molybdenum (Mo). In addition, for example, the wiring barrier film may include one selected from a group including tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material. In the present disclosure, the two-dimensional material may be a metallic material and/or a semiconductor material. The 2D material may include a two-dimensional allotrope or a two-dimensional compound and include, for example, at least one of graphene, molybdenum disulfide (MoS₂), molybdenum diselenide (MoSe₂), tungsten diselenide (WSe₂), and tungsten disulfide (WS₂), but it is merely an example. In other words, since the above-described 2D material is merely mentioned as an example, a 2D material that may be included in the semiconductor device 10 of the present disclosure is not limited to the above-described material.

In an example embodiment, although not illustrated in a drawing, the semiconductor package 10 may include a gate contact. The gate contact may be electrically connected to the wiring line, and the gate electrode 120 may be electrically connected to the wiring line. The gate contact may be a single-layer structure or may be a multilayered structure including a contact filling film and a contact barrier film surrounding at least a portion of a surface of the contact filling film. The gate contact may include a conductive material. For example, the contact filling film may include one selected from a group including aluminum (Al), tungsten (W), cobalt (Co), ruthenium (Ru), copper (Cu), silver (Ag), gold (Au), manganese (Mn), and molybdenum (Mo). In addition, for example, the contact barrier film may include one selected from a group including tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material.

In an example embodiment, at least a portion of the gate contact may be disposed to each of the first gate capping film GP_1 and the second gate capping film GP_2. The gate contact may be disposed by penetrating each of the first gate capping film GP_1 and the second gate capping film GP_2 in the first direction D1.

Referring to FIGS. 6 and 8, a length L₁₃₀₋₁ of the first source/drain area 130-1 in the second direction D2 may be shorter than a length L₁₃₀₋₂ of the second source/drain area 130-2 in the second direction D2.

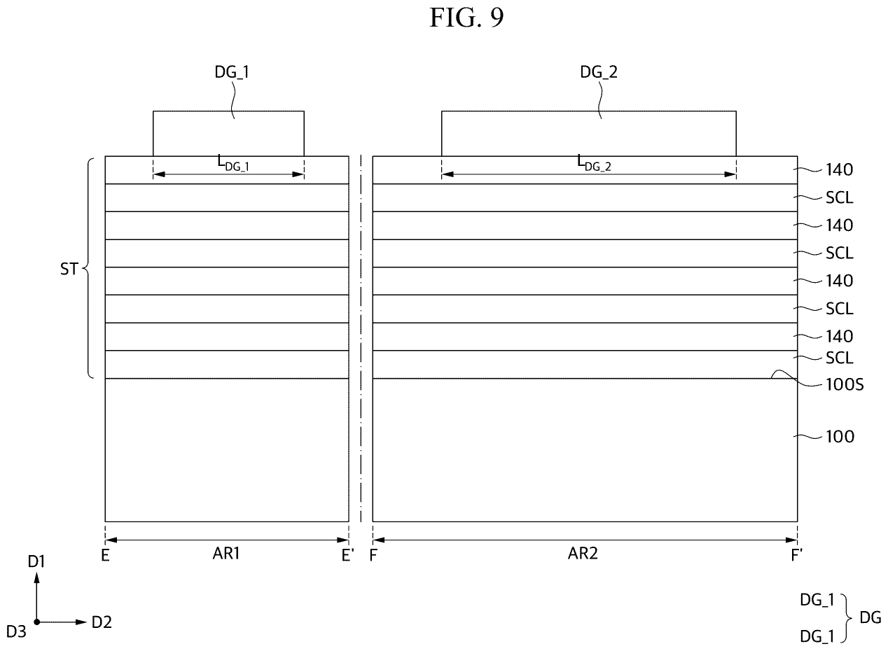

FIGS. 9 through 18 are example diagrams for describing a method of fabricating the semiconductor device 10 according to an example embodiment. In an example embodiment, an already known scheme may be applied to a method of fabricating the semiconductor device 10 unless contradictory thereto. Hereinafter, a scheme for securing the above-described structural property of the semiconductor device 10 will be mainly described.

In the present disclosure, although not particularly limited, a film or a layer may be formed through deposition in an example embodiment. For example, the deposition may be performed through chemical vapor deposition (CVD), physics vapor deposition (PVD), atomic layer deposition (ALD), or the like. Another method used in the art other than the deposition may be applied to formation of a film or a layer. Also, in the present disclosure, although not particularly limited, a film or a layer may be removed through etching. For example, the etching may be performed through dry etching, wet etching that uses phosphoric acid, or the like.

Referring to FIG. 9, in an example embodiment, the method of fabricating the semiconductor device 10 may include forming a stack layer ST by alternately stacking, above the substrate 100, a sacrificial layer SCL and the channel layer 140 disposed on the sacrificial layer SCL. The stack layer ST may include a plurality of sacrificial layers SCL and the plurality of channel layers 140. The sacrificial layer SCL may be formed on the surface 100S of the substrate, and the channel layer 140 may be formed upward in the direction D1 on the sacrificial layer SCL.

Referring to FIG. 9, in an example embodiment, the method of fabricating the semiconductor device 10 may include forming a dummy gate DG on the stack layer ST. The dummy gate DG may include an insulation material. The dummy gate DG may include a first dummy gate DG_1 disposed above the first area AR1 and a second dummy gate DG_2 disposed above the second area AR2. The method of fabricating the semiconductor device 10 may include forming the first dummy gate DG_1 and the second dummy gate DG_2 so that a length L_{DG_1} of the first dummy gate DG_1 in the second direction D2 is shorter than a length L_{DG_2} of the second dummy gate DG_2 in the second direction D2.

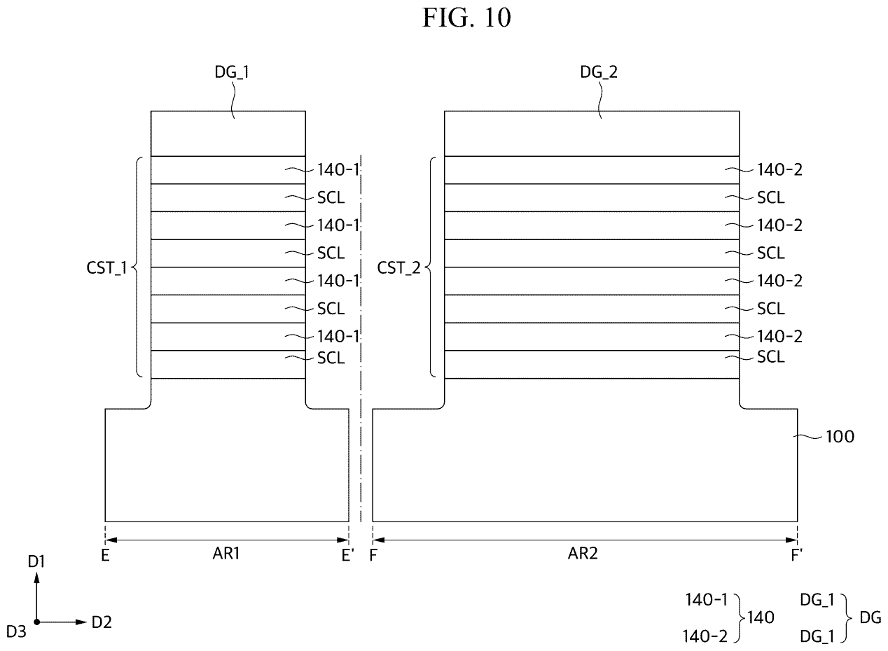

Referring to FIG. 10, in an example embodiment, the method of fabricating the semiconductor device 10 may include etching at least a portion of the stack layer ST, to which the dummy gate is not disposed. The dummy gate DG may serve as a mask. That is, the method of fabricating the semiconductor device 10 may include etching at least the portion of the stack layer ST, which does not overlap the dummy gate DG when viewed in the first direction D1. The method of fabricating the semiconductor device 10 may include etching at least a portion of the substrate 100, which does not overlap the dummy gate DG when viewed in the first direction D1. Through this, a first cut stack layer CST_1 in which the sacrificial layer SCL and the first channel layer 140-1 are alternately stacked, and a second cut stack layer CST_2 in which the sacrificial layer SCL and the second channel layer 140-2 are alternately stacked.

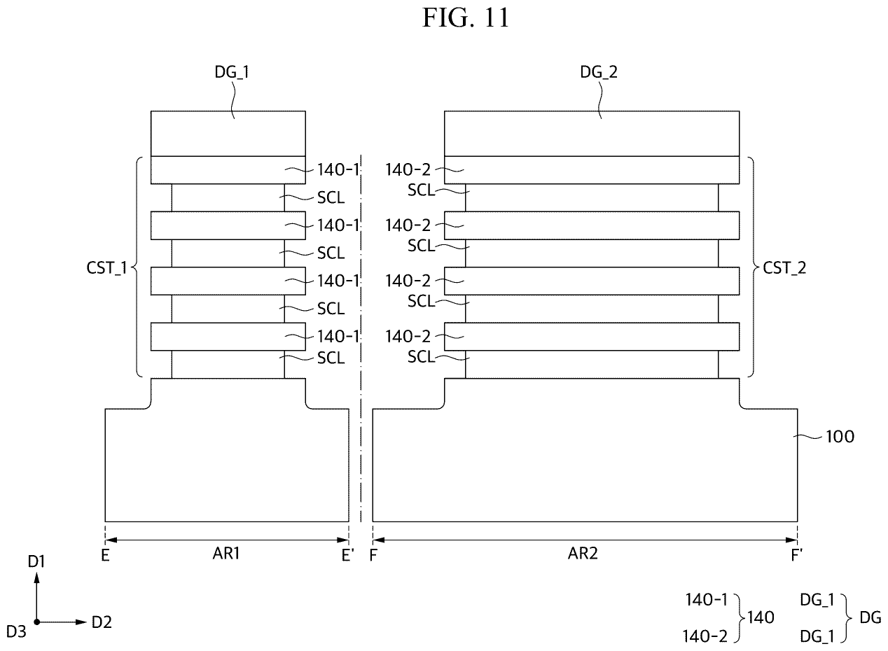

Referring to FIG. 11, in an example embodiment, the method of fabricating the semiconductor device 10 may include etching a portion of the sacrificial layer SCL. The method of fabricating the semiconductor device 10 may include etching portions of the sacrificial layer SCL included in the first cut stack layer CST_1 and the sacrificial layer SCL included in the second cut stack layer CST_2. The sacrificial layer SCL may include a material having high selectivity for the first channel layer 140-1 and the second channel layer 140-2. For example, the first channel layer 140-1 and the second channel layer 140-2 may include silicon (Si), and the sacrificial layer SCL may include one or more of silicon-germanium (SiGe) and aluminum oxide (e.g., A10). The portion of the sacrificial layer SCL may be etched in the second direction D2.

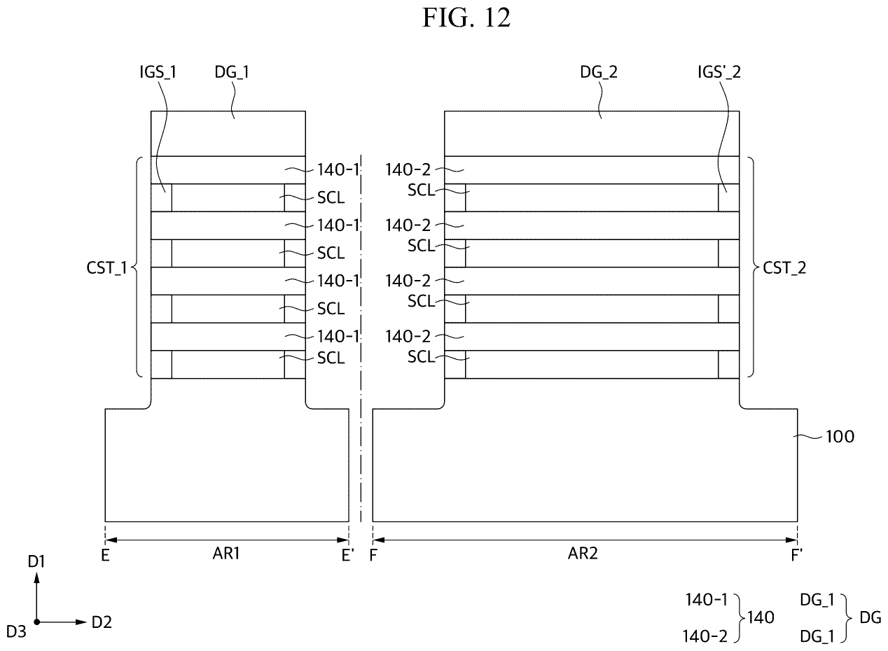

Referring to FIG. 12, in an example embodiment, the method of fabricating the semiconductor device 10 may include forming the first inner spacer IGS_1 and a second inner spacer IGS′_2. The first inner spacer IGS_1 may be formed in an area in which the sacrificial layer SCL is etched in the first cut stack layer CST_1, and the second inner spacer IGS′_2 may be formed in an area in which the sacrificial layer SCL is etched in the second cut stack layer CST_2. The first inner spacer IGS_1 and the second inner spacer IGS′_2 may be formed simultaneously.

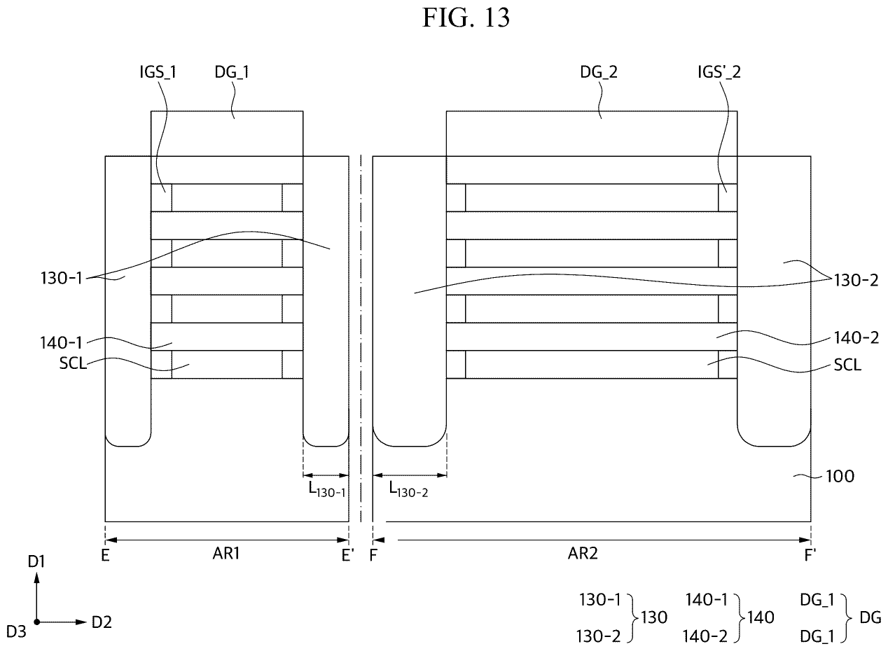

Referring to FIG. 13, in an example embodiment, the method of fabricating the semiconductor device 10 may include forming the source/drain area 130. The method of fabricating the semiconductor device 10 may include forming the first source/drain area 130-1 so that the first source/drain area 130-1 is in contact with the first channel layer 140-1 in at least some areas and forming the second source/drain area 130-2 so that the second source/drain area 130-2 is in contact with the second channel layer 140-2. The first source/drain area 130-1 and the second source/drain area 130-2 may be formed through epitaxial growth. The method of fabricating the semiconductor device 10 may include forming the first source/drain area 130-1 and the second source/drain area 130-2 so that the length L₁₃₀₋₁ of the first source/drain area 130-1 in the second direction D2 is shorter than the length L₁₃₀₋₂ of the second source/drain area 130-2 in the second direction D2.

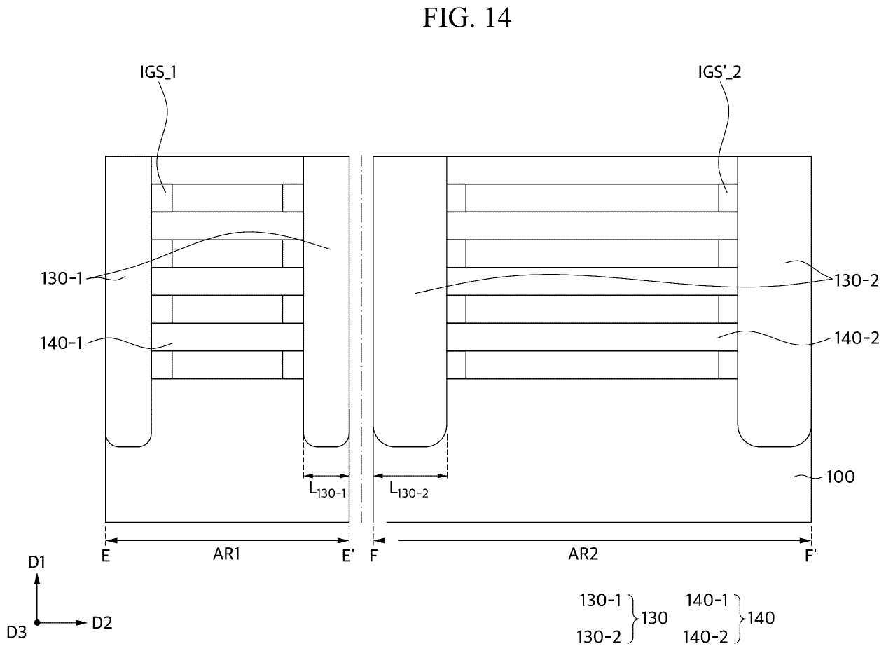

Referring to FIG. 14, in an example embodiment, the method of fabricating the semiconductor device 10 may include removing the sacrificial layer SCL and the dummy gate DG including the first dummy gate DG_1 and the second dummy gate DG_2. The method of fabricating the semiconductor device 10 may include removing the sacrificial layer SCL after removing the dummy gate DG, removing the dummy gate DG after removing the sacrificial layer SCL, or simultaneously removing the dummy gate DG and the sacrificial layer SCL.

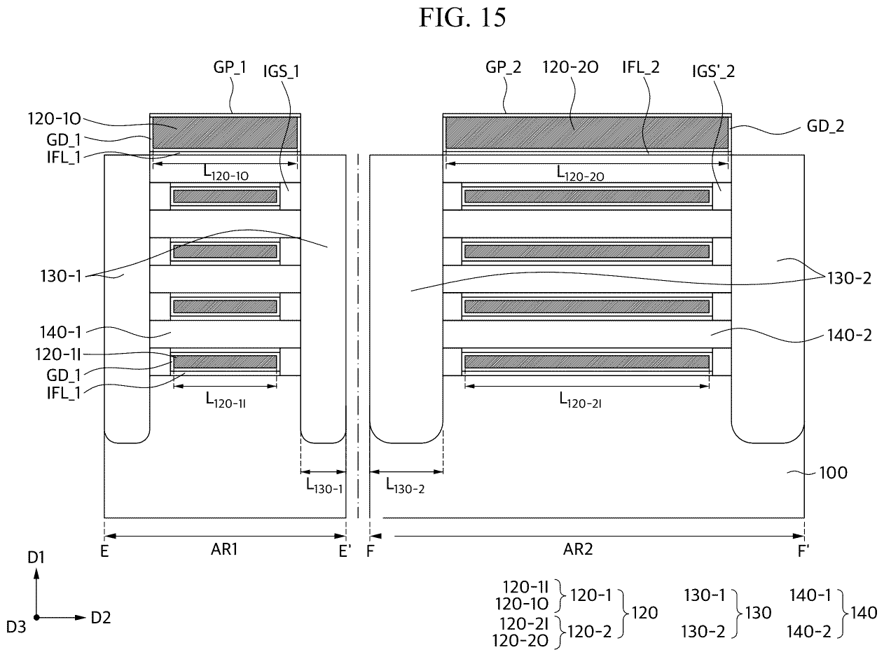

Referring to FIG. 15, in an example embodiment, the method of fabricating the semiconductor device 10 may include forming the gate electrode 120. The method of fabricating the semiconductor device 10 may include forming, in the first area AR1, the first outer gate electrode 120-1O in an area in which the first dummy gate DG_1 is removed and forming the first inner gate electrode 120-1I in an area in which the sacrificial layer SCL is removed. The method of fabricating the semiconductor device 10 may include forming, in the second area AR2, the second outer gate electrode 120-2O in an area in which the second dummy gate DG_2 is removed and forming the second inner gate electrode 120-2I in an area in which the sacrificial layer SCL is removed. In an example embodiment, the length L_{120-1O} of the first outer gate electrode 120-1O in the second direction D2 may be longer than the length L_{120-1I} of the first inner gate electrode 120-1I in the second direction D2. In an example embodiment, the length L_{120-2O} of the second outer gate electrode 120-2O in the second direction D2 may be longer than the length L_{120-2I} of the second inner gate electrode 120-2I in the second direction D2. In an example embodiment, the length L_{120-1O} of the first outer gate electrode 120-1O in the second direction D2 may be shorter than the length L_{120-2O} of the second outer gate electrode 120-2O in the second direction D2. In an example embodiment, the length L_{120-1I} of the first inner gate electrode 120-1I in the second direction D2 may be shorter than the length L_{120-2I} of the second inner gate electrode 120-2I in the second direction D2.

Referring to FIG. 15, in an example embodiment, the method of fabricating the semiconductor device 10 may include forming the first interface film IFL_1 and a second interface film IFL_2. The method of fabricating the semiconductor device 10 may include forming the first gate insulation film GD_1 and the second gate insulation film GD_2. The first gate insulation film GD_1 may surround at least a portion of the first inner gate electrode 120-1I and at least a portion of the first outer gate electrode 120-1O. The second gate insulation film GD_2 may surround at least a portion of the second inner gate electrode 120-2I and at least a portion of the second outer gate electrode 120-2O.

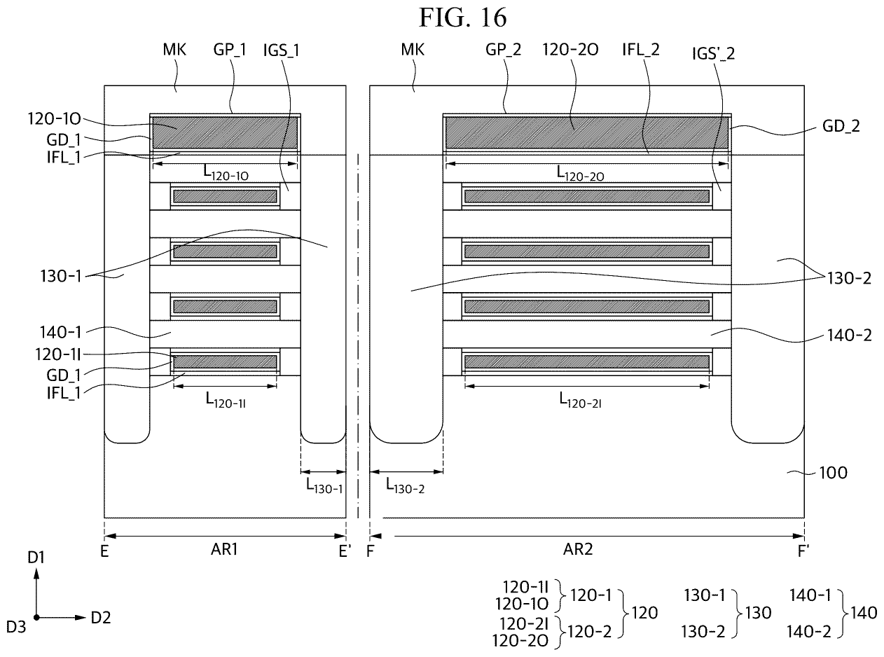

Referring to FIG. 16, in an example embodiment, the method of fabricating the semiconductor device 10 may include forming a mask MK on the first source/drain area 130-1 and the first outer gate electrode 120-1O in the first area AR1 and forming a mask MK on the second source/drain area 130-2 and the second outer gate electrode 120-2O in the second area AR2. Here, masks MK formed above the first area AR1 and the second area AR2 may be formed simultaneously. A mask MK may include silicon, but it is merely an example.

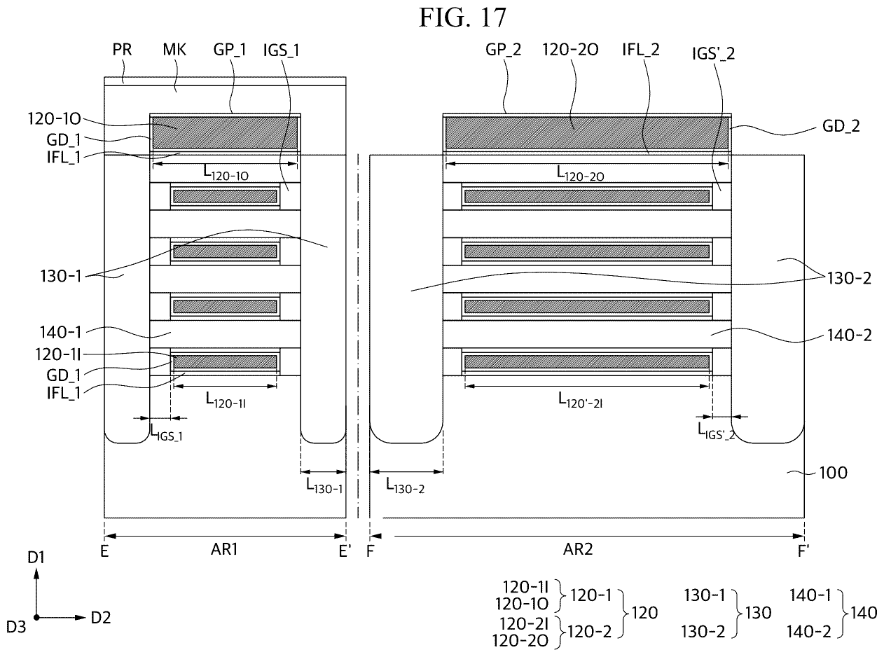

Referring to FIG. 17, the method of fabricating the semiconductor device 10 may include forming a photoresist PR on the mask MK of a short element (e.g., see the first device TR1 of FIG. 7) of which the length L_{120-1I} of the first inner gate electrode 120-1I in the second direction D2 is shorter than the length L_{120-2I} of the second inner gate electrode 120-2I in the second direction D2.

Referring to FIG. 18, the method of fabricating the semiconductor device 10 may include removing the mask MK of a long channel device (e.g., see the second device TR2 of FIG. 8). The mask MK may be removed through a photolithography process or the like.

Referring to FIGS. 17 and 18, the method of fabricating the semiconductor device 10 may include removing a portion of the second inner spacer IGS′_2. Removing the portion of the second inner spacer IGS′_2 may be performed through, for example, a chemical oxide removal (COR) process. In an example embodiment, the length L_{IGS_2} in the second direction D2 of the second inner spacer IGS_2 of which the portion is removed may be shorter than a length L_{IGS′_2} in the second direction D2 of the second inner spacer IGS′_2 of which the portion is not yet removed. In addition, the length L_{IGS_2} in the second direction D2 of the second inner spacer IGS_2 may be shorter than the length L_{IGS_1} in the second direction D2 of the first inner spacer IGS_1. A part in which the portion of the second inner spacer IGS′_2 is removed may be filled with an insulation material and may become one or more of the second gate insulation film GD_2 and the second interface film IFL_2.

While some example embodiments have been described with reference to the accompanying drawings above, the present disclosure is not limited to the above example embodiments and may be manufactured in various forms different from each other. Those skilled in the art to which the present disclosure belongs may understand that other embodiments may be implemented without changing the technical spirit or characteristics of the present disclosure. Therefore, in all aspects, the above-described example embodiments should be understood as non-limiting examples.

What is claimed is:

1. A semiconductor device comprising:
a substrate comprising a first area and a second area;
a first device on the first area; and
a second device on the second area,
wherein the first device comprises
a first channel layer above the first area,
a first inner gate electrode spaced apart from the first channel layer in a first direction crossing a surface of the substrate,
a first source/drain area extending in the first direction and being connected to the first channel layer, and
a first inner spacer between the first inner gate electrode and the first source/drain area, and
wherein the second device comprises
a second channel layer above the second area,
a second inner gate electrode spaced apart from the second channel layer in the first direction,
a second source/drain area extending in the first direction and being connected to the second channel layer, and
a second inner spacer between the second inner gate electrode and the second source/drain area,
wherein a second direction is parallel to the surface of the substrate,
wherein a length of the first inner gate electrode in the second direction is shorter than a length of the second inner gate electrode in the second direction, and
wherein a length of the second inner spacer in the second direction is shorter than a length of the first inner spacer in the second direction.

2. The semiconductor device of claim 1, wherein
the first inner spacer and the first source/drain area do not overlap in the first direction, and
the second inner spacer and the second source/drain area do not overlap in the first direction.

3. The semiconductor device of claim 1, wherein a ratio of the length of the first inner gate electrode in the second direction to the length of the first inner spacer in the second direction is greater than or equal to 1 and less than or equal to 30.

4. The semiconductor device of claim 1, wherein a ratio of the length of the second inner gate electrode in the second direction to the length of the second inner spacer in the second direction exceeds 30.

5. The semiconductor device of claim 1, wherein a ratio of the length of the first inner gate electrode in the second direction to the length of the second inner gate electrode in the second direction is greater than or equal to 0.1 and less than 1.

6. The semiconductor device of claim 1, wherein
the first inner gate electrode overlaps at least a portion of the first source/drain area in the second direction, and
the second inner gate electrode overlaps at least a portion of the second source/drain area overlap in the second direction.

7. The semiconductor device of claim 1, wherein
the first device further comprises a first outer gate electrode,
the first outer gate electrode is spaced apart from the first inner gate electrode in the first direction,
an area of the first outer gate electrode does not overlap the first source/drain area in the second direction,
the second device further comprises a second outer gate electrode,
the second outer gate electrode is spaced apart from the second inner gate electrode in the first direction, and
an area of the second outer gate electrode does not overlap the second source/drain area in the second direction.

8. The semiconductor device of claim 7, wherein a length of the first outer gate electrode in the second direction is shorter than a length of the second outer gate electrode in the second direction.

9. The semiconductor device of claim 8, wherein the length of the first outer gate electrode in the second direction is longer than the length of the first inner gate electrode in the second direction.

10. The semiconductor device of claim 8, wherein the length of the second outer gate electrode in the second direction is longer than the length of the second inner gate electrode in the second direction.

11. The semiconductor device of claim 7, wherein
at least a portion of the first outer gate electrode overlaps the first inner gate electrode in the first direction, and
at least a portion of the second outer gate electrode overlaps the second inner gate electrode in the first direction.

12. The semiconductor device of claim 7, wherein
the first device further comprises a first gate insulation film,
the first gate insulation film surrounds at least a portion of the first channel layer,
the second device comprises a second gate insulation film, and
the second gate insulation film surrounds at least a portion of the second channel layer.

13. The semiconductor device of claim 1, wherein
the first source/drain area comprises a plurality of first source/drain areas, and first source/drain areas adjacent to each other among the plurality of first source/drain areas are spaced apart in the second direction,
the second source/drain area comprises a plurality of second source/drain areas, and second source/drain areas adjacent to each other among the plurality of second source/drain areas are spaced apart in the second direction.

14. The semiconductor device of claim 13, wherein
at least a portion of the first channel layer is between the first source/drain areas adjacent to each other among the plurality of first source/drain areas, and
at least a portion of the second channel layer is between the second source/drain areas adjacent to each other among the plurality of second source/drain areas.

15. The semiconductor device of claim 1, wherein
the first inner gate electrode comprises a plurality of first inner gate electrodes, and first inner gate electrodes adjacent to each other among the plurality of first inner gate electrodes are spaced apart in the first direction,
the first channel layer is between the first inner gate electrodes adjacent to each other among the plurality of first inner gate electrodes,
the second inner gate electrode comprises a plurality of second inner gate electrodes, and second inner gate electrodes adjacent to each other among the plurality of second inner gate electrodes are spaced apart in the first direction, and
the second channel layer is between the second inner gate electrodes adjacent to each other among the plurality of second inner gate electrodes.

16. The semiconductor device of claim 1, wherein
the first inner gate electrode surrounds at least a portion of the first channel layer, and
the second inner gate electrode surrounds at least a portion of the second channel layer.

17. A semiconductor device comprising:
a substrate comprising a first area and a second area;
a first device on the first area; and
a second device on the second area,
wherein the first device comprises
a plurality of first channel layers above the first area and spaced apart from each other,
a first inner gate electrode spaced apart from the plurality of first channel layers in a first direction, the first direction crossing a surface of the substrate,
a first source/drain area extending in the first direction and being connected to the plurality of first channel layers, and
a first inner spacer between the first inner gate electrode and the first source/drain area,
wherein the second device comprises
a plurality of second channel layers above the second area and spaced apart from each other,
a second inner gate electrode spaced apart from the plurality of second channel layers in the first direction,
a second source/drain area extending in the first direction and being connected to the plurality of second channel layers, and
a second inner spacer between the second inner gate electrode and the second source/drain area,
wherein a second direction is parallel to the surface of the substrate,
wherein a length of the first inner gate electrode in the second direction is shorter than a length of the second inner gate electrode in the second direction, and
wherein a length of the second inner spacer in the second direction is shorter than a length of the first inner spacer in the second direction.

18. The semiconductor device of claim 17, wherein
the plurality of first channel layers are spaced apart from each other in the first direction,
the first inner gate electrode is between two of the plurality of first channel layers that are adjacent to each other among the plurality of first channel layers,
the plurality of second channel layers are spaced apart from each other in the first direction, and
the second inner gate electrode is between two of the plurality of second channel layers that are adjacent to each other among the plurality of second channel layers.

19. The semiconductor device of claim 18, wherein
the plurality of first channel layers are spaced apart in the first direction at equal intervals, and
the plurality of second channel layers are spaced apart in the first direction at equal intervals.

20. A semiconductor device comprising:
a substrate comprising a first area and a second area;
a first device on the first area; and
a second device on the second area,
wherein the first device comprises
a plurality of first channel layers above the first area and spaced apart from each other,
a first inner gate electrode spaced apart from the plurality of first channel layers in a first direction, the first direction crossing a surface of the substrate,
a first source/drain area extending in the first direction and being connected to the plurality of first channel layers,
a first inner spacer between the first inner gate electrode and the first source/drain area, and
a first outer gate electrode spaced apart from the first inner gate electrode in the first direction,
wherein the first outer gate electrode does not overlap the first source/drain area in a second direction,
wherein the second direction is parallel to the surface of the substrate,
wherein the second device comprises
a plurality of second channel layers above the second area and spaced apart from each other,
a second inner gate electrode spaced apart from the plurality of second channel layers in the first direction,
a second source/drain area extending in the first direction and being connected to the plurality of second channel layers,
a second inner spacer between the second inner gate electrode and the second source/drain area, and
a second outer gate electrode spaced apart from the second inner gate electrode in the first direction,
wherein an area of the second outer gate electrode does not overlap the second source/drain area in the second direction,
wherein a length of the first inner gate electrode in the second direction is shorter than a length of the second inner gate electrode in the second direction,
wherein a length of the second inner spacer in the second direction is shorter than a length of the first inner spacer in the second direction,
wherein the first inner spacer and the first source/drain area do not overlap in the first direction,
wherein the second inner spacer and the second source/drain area do not overlap in the first direction,
wherein a ratio of the length of the first inner gate electrode in the second direction to the length of the first inner spacer in the second direction is greater than or equal to 1 and less than or equal to 30,
wherein a ratio of the length of the second inner gate electrode in the second direction to the length of the second inner spacer in the second direction exceeds 30,
wherein a ratio of the length of the first inner gate electrode in the second direction to the length of the first inner spacer in the second direction is greater than or equal to 0.1 and less than 1,
wherein at least a portion of the first outer gate electrode overlaps the first inner gate electrode in the first direction, and
wherein at least a portion of the second outer gate electrode overlaps the second inner gate electrode in the first direction.
